(19) United States
(12) Patent Application Publication
(10) Pub. No.: US 2011/0089402 A1
(43) Pub. Date: Apr. 21, 2011

(54) Composite Nanorod-Based Structures for Generating Electricity

(76) Inventor: Pengfei Qi, Menlo Park, CA (US)

(21) Appl. No.: 12/757,825

(22) Filed: Apr. 9, 2010

Related U.S. Application Data
(60) Provisional application No. 61/212,418, filed on Apr. 10, 2009.

(51) Int. Cl. H01L 31/0352; H01L 31/18; B82Y 99/00; B82Y 40/00

(52) U.S. Cl. 257/21; 438/73; 257/E31.033; 977/762; 977/948

(57) ABSTRACT

One aspect of the invention involves an article of manufacture that includes a dielectric layer with an array of pores, and an array of nanowires at least partially contained within the array of pores. A respective nanowire in the array of nanowires is formed within a respective pore in the array of pores. Nanowires in the array of nanowires include a core semiconducting region with a first type of, a shell semiconducting region with a second type of doping, and a junction region between the core semiconducting region and the shell semiconducting. Additionally, the article of manufacture includes a first conducting layer electrically coupled to a plurality of shell semiconducting regions for a plurality of nanowires in the array of nanowires, as well as a second conducting layer electrically coupled to a plurality of core semiconducting regions for a plurality of nanowires in the array of nanowires.

### RELATED APPLICATIONS

This application claims benefit under 35 U.S.C. §119(e) to application Ser. No. 61/212,418, entitled “Composite Nanorod-Based Structures for Generating Electricity,” filed Apr. 10, 2009, the disclosure of which is incorporated herein by reference in its entirety.

### TECHNICAL FIELD

The disclosed embodiments relate generally to structures for photovoltaic energy production. More particularly, the disclosed embodiments relate to structures that use nanorod-based composites to generate photovoltaic energy.

### BACKGROUND

Considerable effort has been put into developing materials and structures for use as solar cells, with limited success. Thus, there remains a need to develop new structures for generating photovoltaic energy that are efficient, low cost, stable, and non-toxic.

### SUMMARY

The present invention addresses the problems described above by providing composite nanowire-based structures for generating photovoltaic energy and methods for making these structures.

One aspect of the invention involves an article of manufacture that includes a dielectric layer with an array of pores, and an array of nanowires at least partially contained within the array of pores. A respective nanowire in the array of nanowires is formed within a respective pore in the array of pores in the dielectric layer. Nanowires in the array of nanowires include a core semiconducting region with a first type of doping and a core region length, a shell semiconducting region with a second type of doping and a shell region length, and a junction region between the core semiconducting region and the shell semiconducting region with a junction region length. The first type of doping used is different from the second type of doping, and the shell region length is less than the core region length. Further, the shell semiconducting region surrounds a portion of the core semiconducting region over a length of the core semiconducting region corresponding to the junction region length. Additionally, the article of manufacture includes a first conducting layer electrically coupled to a plurality of shell semiconducting regions for a plurality of nanowires in the array of nanowires, as well as a second conducting layer, distinct from the first conducting layer, electrically coupled to a plurality of core semiconducting regions for a plurality of nanowires in the array of nanowires.

Another aspect of the invention involves an article of manufacture that includes a freestanding multi-layer composite, which includes a dielectric layer with an array of pores; an array of nanowires at least partially contained within the array of pores, and first and second conducting layers, where the second conducting layer is distinct from the first conducting layer. Respective nanowires in the array of nanowires are formed within respective pores in the array of pores in the dielectric layer. Nanowires in the array of nanowires have: a core semiconducting region with a first type of doping and a core region length; a shell semiconducting region with a second type of doping and a shell region length; and a junction region between the core semiconducting region and the shell semiconducting region with a junction region length. The first type of doping is different from the second type of doping, the shell region length is less than the core region length, and the shell semiconducting region surrounds a portion of the core semiconducting region over a length of the core semiconducting region corresponding to the junction region length. The first conducting layer is electrically coupled to a plurality of shell semiconducting regions for a plurality of nanowires in the array of nanowires, while the second conducting layer is electrically coupled to a plurality of core semiconducting regions for a plurality of nanowires in the array of nanowires.

Another aspect of the invention involves a method that includes: forming an array of nanowires at least partially contained within an array of pores in a dielectric layer; electrically coupling a first conducting layer to a plurality of shell semiconducting regions for a plurality of nanowires in the array of nanowires; and electrically coupling a second conducting layer, distinct from the first conducting layer, to a plurality of core semiconducting regions for a plurality of nanowires in the array of nanowires. A respective nanowire in the array of nanowires is formed within a respective pore in the array of pores in the dielectric layer, and nanowires in the array of nanowires include a number of aspects, including: a core semiconducting region with a first type of doping and a core region length; a shell semiconducting region with a second type of doping and a shell region length; and a junction region between the core semiconducting region and the shell semiconducting region with a junction region length. The first type of doping is different from the second type of doping, the shell region length is less than the core region length, and the shell semiconducting region surrounds a portion of the core semiconducting region over a length of the core semiconducting region corresponding to the junction region length.

Thus, the present invention provides nanowire-based composite structures for photovoltaic energy production and methods for making these structures. Such structures and methods are efficient, low cost, stable, and non-toxic.

### BRIEF DESCRIPTION OF THE DRAWINGS

For a better understanding of the aforementioned aspects of the invention as well as additional aspects and embodiments thereof, reference should be made to the Description of Embodiments below, in conjunction with the following drawings in which like reference numerals refer to corresponding parts throughout the figures. For clarity, features in some figures are not drawn to scale.

FIGS. 1-12 are schematic cross sections illustrating a method of making a nanowire-based composite in accordance with some embodiments.

FIG. 13A is a schematic cross section illustrating an article of manufacture of a nanowire-based composite in accordance with some embodiments.

FIGS. 13B-13F depict nanowire cross sections in accordance with some embodiments.

FIG. 14 is a schematic cross section illustrating an article of manufacture of a nanowire-based composite in accordance with some embodiments.

### DESCRIPTION OF EMBODIMENTS

The disclosed embodiments relate to structures that use nanowire-based composites to generate photovoltaic energy and methods for making these structures. As used in the specification and claims, “nanorod” or, equivalently “nanowire,” refers to inorganic structures with micron or sub-micron cross-section dimensions and aspect ratios greater than 5. For example, a cylindrical silicon-based rod with a 300 nm diameter and 10 micron length is a nanorod/nanowire.

In the following description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” another layer, it can be directly on the other layer or intervening layers may also be present. In contrast, when a layer is referred to as “contacting” another layer, there are no intervening layers present. Similarly, it will be understood that when a layer is referred to as being “below” another layer, it can be directly under the other layer or intervening layers may also be present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

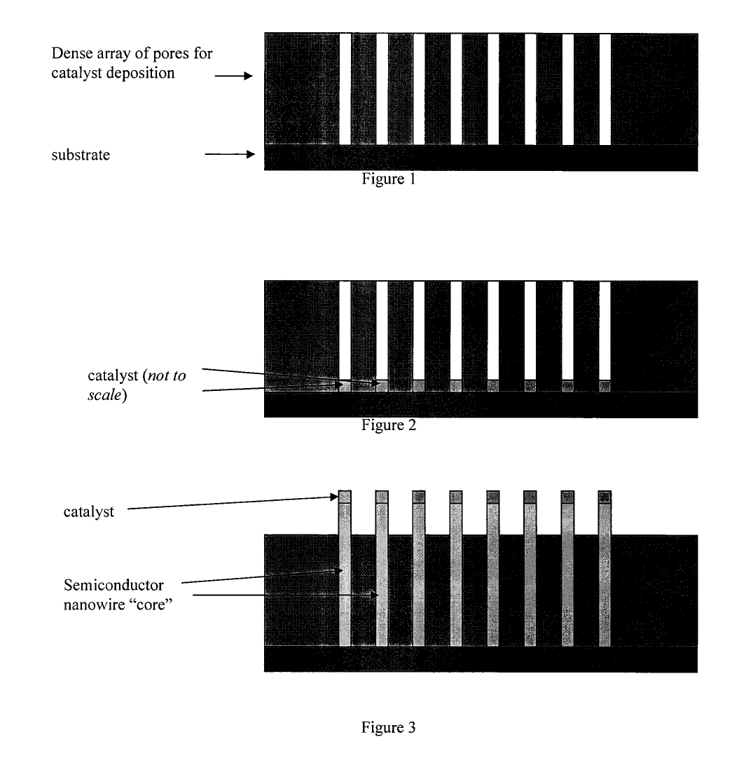

FIGS. 1-12 are schematic cross sections illustrating a method of making a nanowire-based composite in accordance with some embodiments.

The nanowires are formed within a dielectric layer with an array of pores or holes (see, e.g., FIG. 1). In some embodiments, the dielectric layer is an oxide. In some embodiments, the dielectric layer is porous aluminum oxide. The substrate underneath the porous dielectric layer may be aluminum (e.g. an aluminum foil), another metal, ITO, or another conducting layer. In some embodiments, the porous aluminum oxide is formed by anodizing an aluminum substrate. In some embodiments, the porous aluminum oxide is formed by depositing an aluminum film on a conducting layer/substrate (e.g., by sputtering) and then anodizing the aluminum film. Exemplary methods for forming a porous dielectric layer are known, such as the methods discussed in the following articles, all of which are incorporated by reference in their entireties: Fast fabrication of long-range ordered porous alumina membranes by hard anodization, Lee et al., Nature Materials, Vol. 5 Sep. 2006, pgs. 741-747; Fabrication of carbon nanotube emitters in an anodic aluminum oxide nanotemplate on a Si wafer by multi-step anodization, Hwang et al., Nanotechnology 16 (2005) pgs. 850-858; and Template-based synthesis of nanomaterials, Huczko, Appl. Phys A 70, 365-376 (2000).

In some embodiments, the substrate is a conducting layer that is physically and electrically coupled to the plurality of core semiconductor regions in the array of nanowires.

In some embodiments, a catalyst is deposited into the bottom of the holes (FIG. 2). In some embodiments, the catalyst layer is formed in the holes of a porous aluminum oxide film. In some embodiments, the catalyst completely covers the bottom of the holes. In some embodiments, a gold alloy may be used as the catalyst. In some embodiments, other metals such as nickel, copper or alloys thereof may be used as the catalyst. In some embodiments, the catalyst can be deposited into the bottom of the holes by electroplating.

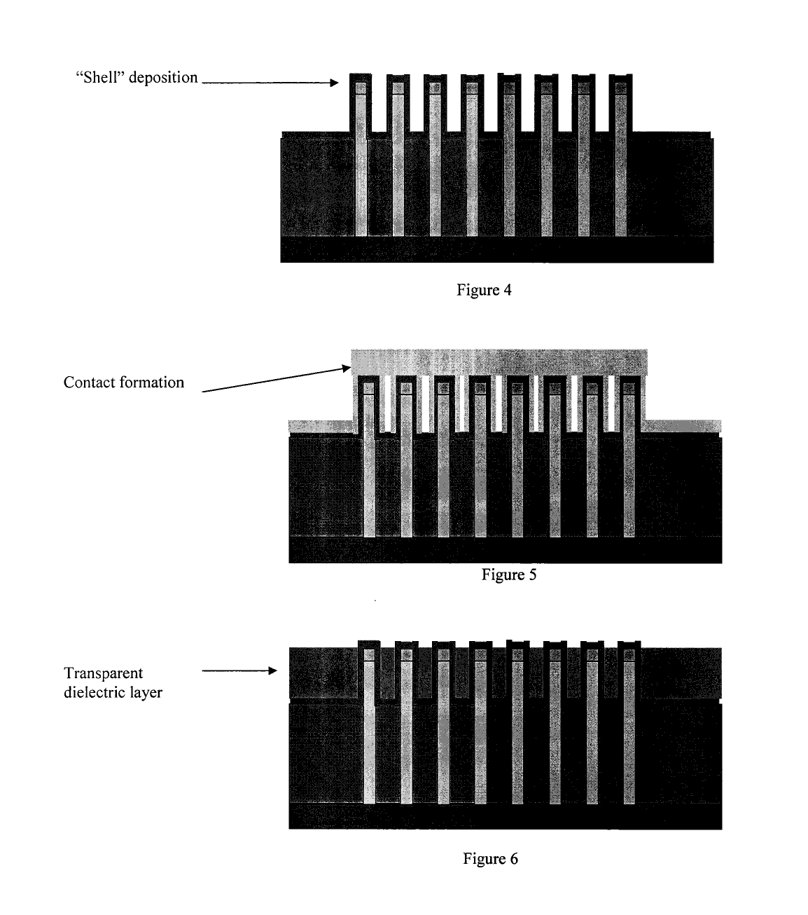

An array of nanowires is formed on the substrate, with at least a portion of the array of nanowires at least partially contained within the array of pores. (FIG. 3). Nanowires in the array of nanowires include at least three aspects: (1) a core semiconducting region with a first type of doping and a core region length; (2) a shell semiconducting region with a second type of doping and a shell region length (FIG. 4); and (3) a junction region between the core semiconducting region and the shell semiconducting region with a junction region length.

In some embodiments, the core semiconductor regions are partially contained within the array of pores, and also extend out beyond the top surface of the porous dielectric layer (FIG. 3). In some embodiments, the shell semiconducting regions are formed on the core semiconductor regions that extend beyond the top surface of the porous dielectric layer (FIG. 4), as described further below.

In some embodiments, the core region length is between 1-200 μm.

In some embodiments, respective nanowires in the array of nanowires comprise single-crystalline silicon.

In some embodiments, the shell region length is between 50-95% of the core region length. Alternatively, the shell region length is between 80-90% of the core region length. Alternatively, the shell region length is the same as or substantially the same as the junction region length.

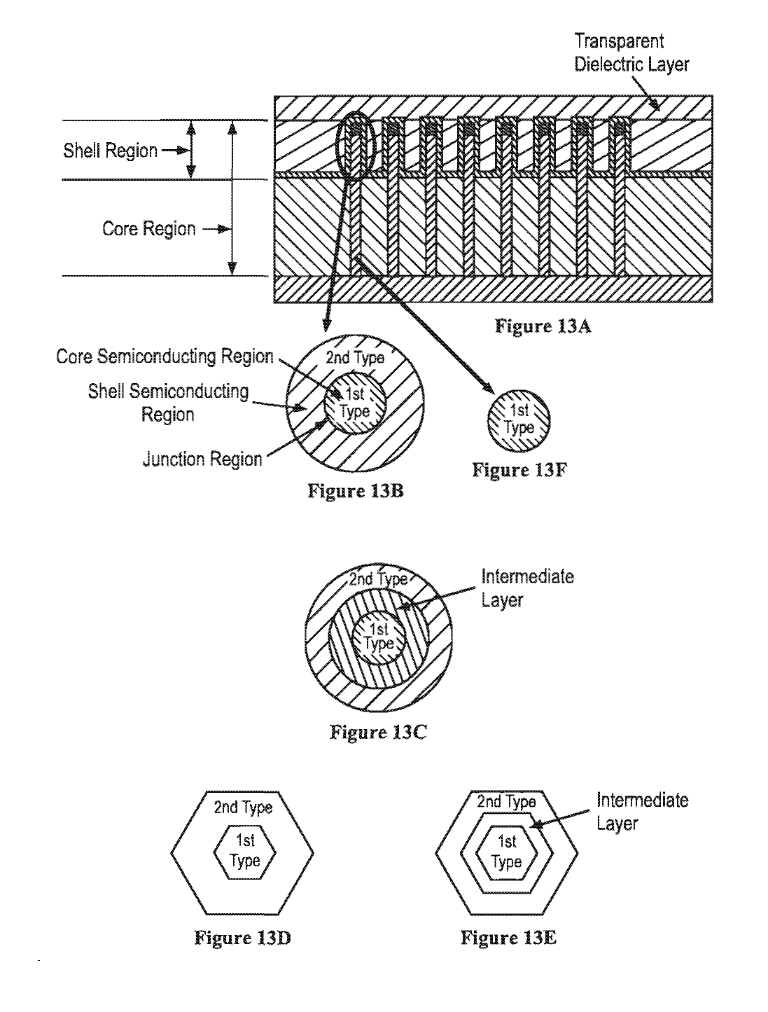

In some embodiments, an intermediate region is included between the core semiconducting region and the shell semiconducting region (see, e.g., FIG. 13C, discussed further below).

With respect to the nanowires, the first type of doping is different from the second type of doping, the shell region length is less than the core region length, and the shell semiconducting region surrounds a portion of the core semiconducting region over a length of the core semiconducting region corresponding to the junction region length.

In some embodiments, the first type of doping is p-type and the second type of doping is n-type, while in other embodiments, the first type of doping is n-type and the second type of doping is p-type.

In some embodiments, the array of nanowires is formed by vapor-liquid-solid (VLS) growth (described further below).

A conducting layer is deposited on top of the “shell” semiconducting layer. (FIG. 5) The conducting layer is electrically coupled to a plurality of shell semiconducting regions for a plurality of nanowires in the array of nanowires.

In some embodiments, the conducting layer is Indium Tin Oxide (“ITO”). In some embodiments, the conducting layer is Zinc Oxide (“ZnO”).

In some embodiments, a transparent dielectric layer is deposited on top of the nanowire array before the conducting layer is deposited. (FIG. 6) In some embodiments, the transparent dielectric layer comprises polydimethylsiloxane (PDMS). In some embodiments, the transparent dielectric layer comprises a polyxylylene polymer, such as Parylene.

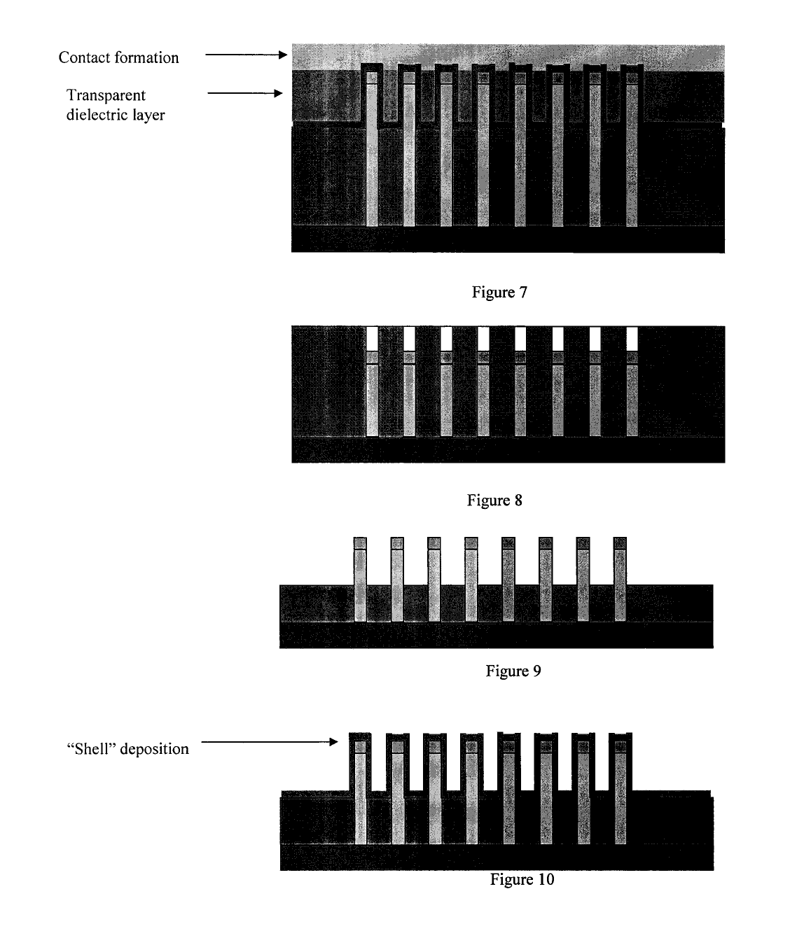

Following the optional deposition of the transparent dielectric layer, a conducting layer is deposited to form contact with the “shell” semiconducting layer (FIG. 7).

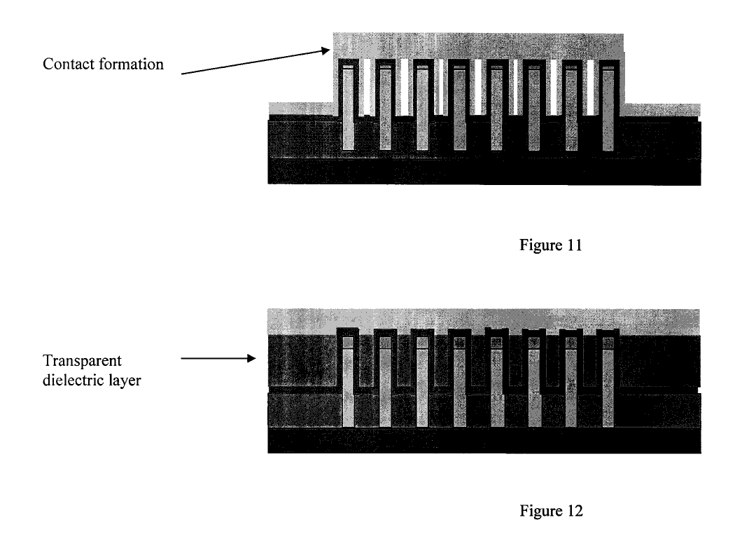

In some embodiments, after the catalyst is deposited (FIG. 2), the array of nanowires is formed on the substrate and completely embedded inside the dielectric layer (FIG. 8). In these embodiments, a portion of the dielectric layer is removed (e.g., by etching, such as wet etching with sulfuric acid, or plasma etching) in order to expose a portion of embedded nanowires to act as “core” region. The core semiconducting regions of the array of nanowires are formed with a first type of doping. (FIG. 9). Additionally, a semiconducting layer of a second type of doping is deposited conformally as the “shell” on top of the array of nanowires (FIG. 10). A conducting layer is deposited on top of the shell semiconducting layer (FIG. 11). In some embodiments, a transparent dielectric layer is deposited on top of the nanowire array before the conducting layer is deposited (FIG. 12).

FIG. 13A is a schematic cross section illustrating an article of manufacture of a nanowire-based composite in accordance with some embodiments.

The circled area in FIG. 13A is the junction area of an individual nanowire, and in FIG. 13B, the cross section of an exemplary nanowire is depicted. A core semiconducting region is formed with a first type of doping and a shell semiconducting region is formed with a second type of doping. In some embodiments, another intermediate region is formed between the core semiconducting region and the shell semiconducting region (FIG. 13C). In some embodiments, the intermediate region may be selected from the group consisting of single-crystalline silicon, poly-crystalline silicon, and amorphous silicon. In some embodiments, the nanowires have a cylindrical shape with a circular cross section (e.g., FIG. 13B and FIG. 13C). In some embodiments, the nanowires have a polygonal cross section (e.g., FIG. 13D, FIG. 13E). The portion of the nanowires that is embedded inside the dielectric layer is just the “core” region. (FIG. 13F)

The article of manufacture includes a dielectric layer with an array of pores. The dielectric layer includes an array of nanowires at least partially contained within the array of pores, wherein a respective nanowire in the array of nanowires is formed within a respective pore in the array of pores in the dielectric layer.

The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length (FIG. 13B).

In some embodiments, the width/diameter of the nanowires may range between 100-1000 nm, 100-400 nm, 200-300 nm, or may be about 250 nm.

The first type of doping is different from the second type of doping. The shell region length is less than the core region length (FIG. 13A). The shell semiconducting region surrounds a portion of the core semiconducting region over a length of the core semiconducting region corresponding to the junction region length.

The article of manufacture also includes a first conducting layer either on top of the dielectric layer, or contacting the dielectric layer. The first conducting layer comprises a conducting material, and the first conducting layer is electrically coupled to a plurality of shell semiconducting regions for a plurality of nanowires in the array of nanowires.

The article of manufacture also includes a second conducting layer, distinct from the first conducting layer, wherein the second conducting layer is either below the porous dielectric layer, or contacting the bottom surface of the porous dielectric layer. The second conducting layer also comprises a conducting material, and the second conducting layer is electrically coupled to a plurality of core semiconducting regions for a plurality of nanowires in the array of nanowires. As noted above, in some embodiments, the second conducting layer is the substrate on which the array of nanowires was formed (e.g., an aluminum substrate).

In some embodiments, a portion of the nanowire array is embedded in the dielectric layer. In some embodiments, the dielectric layer comprises a porous membrane with an array of pores. In some embodiments, the dielectric layer comprises an aluminum oxide membrane.

In some embodiments, the first type of doping is p-type and the second type of doping is n-type. In some embodiments, the first type of doping is n-type and the second type of doping is p-type.

In some embodiments, the core region length may range between 1 μm-1 mm, 50-200 μm, 50-100 μm, 80-100 μm, or may be about 100 μm.

In some embodiments, the nanowire comprises silicon. In some embodiments, respective nanowires in the array of nanowires comprise single-crystalline silicon. In some embodiments, a respective single-crystalline nanowire includes a single-crystalline core semiconducting region with a first type of doping (e.g., p-type) and a single-crystalline shell semiconducting region with a second type of doping (e.g., n-type). In some embodiments, a respective silicon nanowire includes a single-crystalline core semiconducting region with a first type of doping (e.g., p-type) and a poly-crystalline shell semiconducting region with a second type of doping (e.g., n-type). In some embodiments, a respective silicon nanowire includes a single-crystalline core semiconducting region with a first type of doping (e.g., p-type) and an amorphous shell semiconducting region with a second type of doping (e.g., n-type). In some embodiments, a respective nanowire includes a single-crystalline core semiconducting region with a first type of doping (e.g., p-type), a shell (single-crystalline, poly-crystalline or amorphous) semiconducting region with a second type of doping (e.g., n-type), and an intermediate region (single-crystalline, or poly-crystalline or amorphous) between the core semiconducting region and the shell semiconducting region (e.g., FIG. 13).

In some embodiments, the nanowire comprises germanium. In some embodiments, the nanowire comprises silicon-germanium. In some embodiments, the nanowire comprises InGaN. In some embodiments, the nanowire comprises GaAs. In some embodiments, the nanowire comprises a III-V or II-VI semiconductor.

In some embodiments, the core region is made of a first semiconducting material and the shell region is made of a second semiconducting material that is different from the first semiconducting material. For example, the nanowire may be made with various core-shell material combinations, such as: a silicon core/germanium shell; a germanium core/silicon shell; a silicon core/III-V semiconductor shell; a silicon core/II-VI semiconductor shell; a germanium core/III-V semiconductor shell; or a germanium core/II-VI semiconductor shell.

In some embodiments, the shell region length is between 50-95% of the core region length. In some embodiments, the shell region length is between 80-90% of the core region length. In some embodiments, the shell region length is the same as or substantially the same as the junction region length.

In some embodiments, the first conducting layer comprises a metal. In some embodiments, the first conducting layer comprises ITO.

In some embodiments, the second conducting layer comprises a metal. In some embodiments, the second conducting layer comprises ITO.

In some embodiments, nanowires in the array of nanowires include an intermediate region between the core semiconducting region and the shell semiconducting region (e.g., FIGS. 13C and 13E).

In some embodiments, the article of manufacture includes an encapsulant layer on top of the first conducting layer. In some embodiments, the article of manufacture includes an encapsulant layer on top of the second conducting layer. In some embodiments, the article of manufacture includes an encapsulant layer on top of both the first and second conducting layers.

In some embodiments, the article of manufacture includes a polymer encapsulant layer on top of the first conducting layer. In some embodiments, the article of manufacture includes a polymer encapsulant layer on top of the second conducting layer. In some embodiments, the article of manufacture includes a polymer encapsulant layer on top of both the first and second conducting layers. In some embodiments, the polymer encapsulant layer(s) comprise a polyurethane resin.

In some embodiments, a freestanding multi-layer composite (not depicted in the figures) includes a dielectric layer with an array of pores, and an array of nanowires at least partially contained within the array of pores, wherein a respective nanowire in the array of nanowires is formed within a respective pore in the array of pores in the dielectric layer. The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length.

In the freestanding multi-layer composite, the first type of doping is different from the second type of doping. The shell region length is less than the core region length. The shell semiconducting region surrounds a portion of the core semiconducting region over a length of the core semiconducting region corresponding to the junction region length.

The freestanding multi-layer composite includes a first conducting layer electrically coupled to a plurality of shell semiconducting regions for a plurality of nanowires in the array of nanowires, and a second conducting layer, distinct from the first conducting layer, electrically coupled to a plurality of core semiconducting regions for a plurality of nanowires in the array of nanowires.

Nanowire-based composites enable multiple layers of thin film solar cells to be easily stacked, without the lattice matching problems that traditional multi-j unction solar cell manufacturers face. By stacking up multiple freestanding composite films, the efficiency can be increased. Different films can contain different semiconductor materials with different bandgaps to maximize the adsorption of sunlight. The core-shell structures in the different films in the stack can also vary in terms of length, density, layer thickness, core-shell switch, etc.

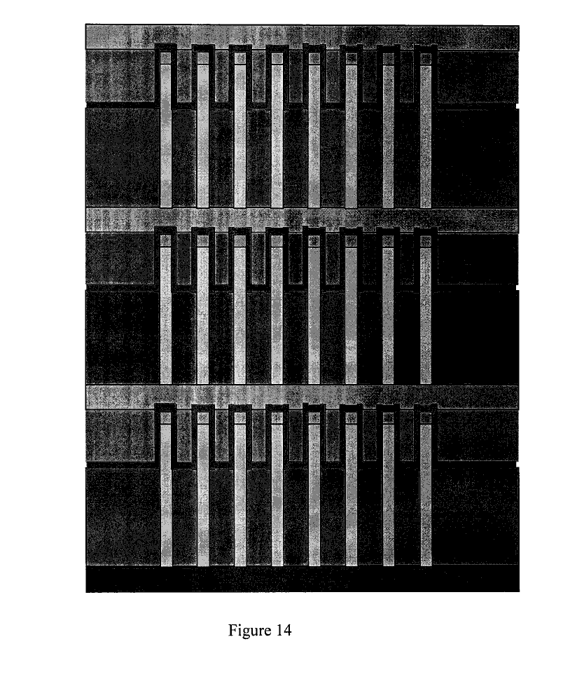

FIG. 14 is a schematic cross section of an article of manufacture in accordance with some embodiments. The article of manufacture depicted includes a freestanding stack of composite films. In some embodiments, individual composite films in the freestanding stack of composite films are analogous to the article of manufacture depicted in FIG. 13A, while in other embodiments, individual composite films in the freestanding stack of composite films may include fewer layers than the article of manufacture depicted in FIG. 13A.

At least some of the composite films in the stack of composite films include a dielectric layer with an array of pores, and array of nanowires at least partially contained within the array of pores, wherein a respective nanowire in the array of nanowires is formed within a respective pore in the array of pores in the dielectric layer. The nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length.

The first type of doping is different from the second type of doping. The shell region length is less than the core region length. The shell semiconducting region surrounds a portion of the core semiconducting region over a length of the core semiconducting region corresponding to the junction region length.

In the stack of composite films, at least some of the composite films include a first conducting layer either on top of the porous dielectric layer, or contacting the porous dielectric layer. The first conducting layer comprises a conducting material, and the first conducting layer is electrically coupled to a plurality of shell semiconducting regions for a plurality of nanowires in the array of nanowires. In some embodiments, the first conducting layer is a transparent conducting layer such as ITO, or another suitable transparent, conducting material.

In the stack of composite films, at least some of the composite films include a second conducting layer, distinct from the first conducting layer, wherein the second conducting layer is either below the dielectric layer, or contacting the bottom surface of the dielectric layer. The second conducting layer also comprises a conducting material, and the second conducting layer is electrically coupled to a plurality of core semiconducting regions for a plurality of nanowires in the array of nanowires. In some embodiments, the second conducting layer for individual composite films in the stack of composite films is a transparent conducting layer such as ITO, or another suitable transparent, conducting material, while the second conducting layer for the bottom-most composite film in the stack of composite films is a substrate as discussed above (e.g., an aluminum foil).

In some embodiments, some of the composite films in a given stack of composite films may include the second conducting layer, while other films in a given stack of composite films do not include the second conducting layer.

As noted above, in some embodiments, the nanowires are formed using a vapor-liquid-solid (VLS) growth process. In some embodiments, the nanowires are formed in the following manner.

A thin catalyst layer (e.g. 10-300 nm thick) is deposited in the holes of a dielectric layer with an array of pores, e.g., a porous aluminum oxide membrane, or other suitable dielectric layer with an array of pores as discussed above. In some embodiments, a gold alloy may be used as the catalyst. In some embodiments, other metals such as nickel, copper or alloys thereof may be used as the catalyst. The catalyst layer fills the bottom of the pores.

In some embodiments, the core semiconducting region for a respective nanowire is formed by flowing silane, hydrogen, and diborane (for p-type doping of the core region) over the aluminum oxide membrane substrate in a CVD chamber at 400-500° C. Exemplary processing parameters are:
460° C. growth temperature
40-100 torr total pressure (e.g., 50 torr)
50 sccm 2% silane (with the balance argon or another inert gas)
10 sccm hydrogen
10 sccm 100 ppm diborane (with the balance argon or another inert gas)
   For these processing parameters, the nanowires grow at about 1.0-1.5 μm/minute.

In some embodiments, an intermediate region for a respective nanowire is formed adjacent to the core semiconducting region by stopping the silane and diborane flows, increasing the CVD chamber temperature (e.g., to 640° C.), and then flowing 10 sccm 2% silane (with the balance argon or another inert gas) and 60 sccm hydrogen at 640° C. and 50 torr total pressure until the desired undoped semiconducting region thickness is reached.

In some embodiments, a shell semiconducting region for a respective nanowire is formed adjacent to the undoped semiconducting region (or adjacent to the core semiconducting region if no undoped semiconducting region is present) by flowing 10 sccm 2% silane (with the balance argon or another inert gas), 5 sccm 100 ppm phosphine (with the balance argon or another inert gas), and 60 sccm hydrogen at 640° C. and 50 torr total pressure until the desired shell semiconducting region thickness is reached.

The nanowire-based composites described above may be incorporated into photovoltaic energy conversion devices and systems. Exposing the composites to sunlight will generate electricity via the photovoltaic effect.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. An article of manufacture, comprising:
a dielectric layer with an array of pores;
an array of nanowires at least partially contained within the array of pores, wherein:
a respective nanowire in the array of nanowires is formed within a respective pore in the array of pores in the dielectric layer; and
nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length;
wherein the first type of doping is different from the second type of doping;
wherein the shell region length is less than the core region length;
wherein the shell semiconducting region surrounds a portion of the core semiconducting region over a length of the core semiconducting region corresponding to the junction region length;
a first conducting layer electrically coupled to a plurality of shell semiconducting regions for a plurality of nanowires in the array of nanowires; and
a second conducting layer, distinct from the first conducting layer, electrically coupled to a plurality of core semiconducting regions for a plurality of nanowires in the array of nanowires.

2. The article of manufacture of claim 1, wherein the dielectric layer comprises an oxide.

3. The article of manufacture of claim 1, wherein the dielectric layer comprises aluminum oxide.

4. The article of manufacture of claim 1, wherein the first type of doping is p-type and the second type of doping is n-type.

5. The article of manufacture of claim 1, wherein the first type of doping is n-type and the second type of doping is p-type.

6. The article of manufacture of claim 1, wherein the core region length is between 1-200 μm.

7. The article of manufacture of claim 1, wherein respective nanowires in the array of nanowires comprise single-crystalline silicon.

8. The article of manufacture of claim 1, wherein the shell region length is between 50-95% of the core region length.

9. The article of manufacture of claim 1, wherein the shell region length is between 80-90% of the core region length.

10. The article of manufacture of claim 1, wherein the shell region length is the same as or substantially the same as the junction region length.

11. The article of manufacture of claim 1, including an intermediate region between the core semiconducting region and the shell semiconducting region.

12. The article of manufacture of claim 1, including an encapsulant layer on top of both the first conducting layer and the second conducting layer.

13. The article of manufacture of claim 1, further comprising a transparent dielectric layer on top of the array of nanowires.

14. The article of manufacture of claim 13, wherein the transparent dielectric layer contacts the array of nanowires.

15. An article of manufacture, comprising:
a freestanding multi-layer composite, including:
a dielectric layer with an array of pores;
an array of nanowires at least partially contained within the array of pores, wherein:
a respective nanowire in the array of nanowires is formed within a respective pore in the array of pores in the dielectric layer; and
nanowires in the array of nanowires have:
a core semiconducting region with a first type of doping and a core region length;
a shell semiconducting region with a second type of doping and a shell region length; and
a junction region between the core semiconducting region and the shell semiconducting region with a junction region length;
wherein the first type of doping is different from the second type of doping;
wherein the shell region length is less than the core region length;
wherein the shell semiconducting region surrounds a portion of the core semiconducting region over a length of the core semiconducting region corresponding to the junction region length;
a first conducting layer electrically coupled to a plurality of shell semiconducting regions for a plurality of nanowires in the array of nanowires; and
a second conducting layer, distinct from the first conducting layer, electrically coupled to a plurality of core semiconducting regions for a plurality of nanowires in the array of nanowires.

16. A method, comprising:
forming an array of nanowires at least partially contained within an array of pores in a dielectric layer, wherein:
a respective nanowire in the array of nanowires is formed within a respective pore in the array of pores in the dielectric layer; and
nanowires in the array of nanowires include:
a core semiconducting region with a first type of doping and a core region length;
a shell semiconducting region with a second type of doping and a shell region length; and
a junction region between the core semiconducting region and the shell semiconducting region with a junction region length;
wherein the first type of doping is different from the second type of doping;
wherein the shell region length is less than the core region length;
wherein the shell semiconducting region surrounds a portion of the core semiconducting region over a length of the core semiconducting region corresponding to the junction region length;
electrically coupling a first conducting layer to a plurality of shell semiconducting regions for a plurality of nanowires in the array of nanowires; and
electrically coupling a second conducting layer, distinct from the first conducting layer, to a plurality of core semiconducting regions for a plurality of nanowires in the array of nanowires.

17. The method of claim 16, including forming an intermediate region between the core semiconducting region and the shell semiconducting region.

18. The method of claim 16, wherein the dielectric layer comprises an oxide.

19. The method of claim 16, wherein the dielectric layer comprises aluminum oxide.

20. The method of claim 16, including depositing a first encapsulation layer on the first conducting layer and depositing a second encapsulation layer on the second conducting layer.
